(19) United States
(12) Patent Application Publication
(10) Pub. No.: US 2016/0190163 A1
(43) Pub. Date: Jun. 30, 2016

(54) TFT ARRAY SUBSTRATE AND METHOD FOR MANUFACTURING THE SAME, AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Qiangqiang Luo, Beijing (CN); Jiujuan Yang, Beijing (CN)

(21) Appl. No.: 14/802,551

(22) Filed: Jul. 17, 2015

(30) Foreign Application Priority Data
Oct. 24, 2014 (CN) 201410577032.8

(51) Int. Cl. H01L 27/12

(52) U.S. Cl. CPC H01L 27/124; H01L 27/1288; H01L 27/1262; H01L 27/1237

(57) ABSTRACT

Embodiments of the present disclosure provide a method for manufacturing a TFT array substrate. The method comprises, forming a passivation layer on a substrate formed with a data line, the passivation layer including a first portion of passivation layer over the data line and a second portion of passivation layer over regions other than the data line; and reducing the first portion of passivation layer by a first preset thickness, so that a thickness of the first portion of passivation layer is less than a thickness of the second portion of passivation layer. In abovementioned method, since a portion of passivation layer over the data line is reduced by certain thickness so that the thickness of the passivation layer over the data line is less than the thickness of the passivation layer over regions other than the data line, it achieves a smaller drop height caused by the data line, thereby alleviating or overcoming problems such as light leakage, contrast decay caused by presence of the drop height in the array substrate, and achieving better display quality. Embodiments of the present disclosure also provide a TFT array substrate and a display device comprising the abovementioned TFT array substrate.

### CROSS-REFERENCE TO RELATED APPLICATION

This application claims the benefit of Chinese Patent Application No. 201410577032.8filed on Oct. 24, 2014 in the State Intellectual Property Office of China, the whole disclosure of which is incorporated herein by reference.

### BACKGROUND

1. Technical Field

The present disclosure relates to the field of display technologies, and particularly, to a Thin Film Transistor (TFT) array substrate and a method for manufacturing the same, and a display device.

2. Description of the Related Art

Thin Film Transistor Liquid Crystal Display (TFT-LCD) device holds dominant position in the market of flat panel display device due to its advantages including small in size, low in power consumption and radiationless. With development of the technology, higher requirements on display quality of the display device is made by customers, and pursuit of performances liking higher transmittance, wider viewing angle, higher aperture ratio, lower chromatic aberration, and lower response time promotes the rapid development of display technology.

Important components of the TFT-LCD include a TFT array substrate having an alignment layer at its surface facing liquid crystals. The method of manufacturing the alignment layer comprises two steps of Polyimide (PI) coating process and friction process. The friction process comprises performing a friction on a coated PI film with friction fabric, to form groove marks with certain direction on the PI film. These groove marks ensures that liquid crystals are orderly arranged in a predetermined angle when no electrical field is applied. Amount of the predetermined angle caused by the friction process changes as friction conditions, materials for PI film and flatness of surface of the substrate change.

Referring to FIG. 1, in a TFT array substrate for TFT-LCD, data line 13 on a substrate 11 generally has a height greater than heights of other components (e.g., pixel electrode 12) laid on other locations of the same film layer, correspondingly, a height of a section of a passivation layer 14 over the data line 13 is greater than those of other sections of the passivation layer 14 over positions other than the data line 13, and a difference between the height of the section of the passivation layer 14 over the data line 13 and those of other sections of the passivation layer 14 over positions other than the data line 13 is a drop height a. Such drop height a will adversely affect friction effect of the PI film subsequently, resulting in that liquid crystals in such position cannot be driven normally, thereby causing problems such as light leakage, contrast decay, and the likes.

### SUMMARY

According to one aspect of the present disclosure, there is provided a method for manufacturing a TFT array substrate, the method comprising:

forming a passivation layer on a substrate formed with a data line, the passivation layer including a first portion of passivation layer over the data line and a second portion of passivation layer over regions other than the data line; and

reducing the first portion of passivation layer by a first preset thickness, so that a thickness of the first portion of passivation layer is less than a thickness of the second portion of passivation layer.

According to another aspect of the present disclosure, there is provided a TFT array substrate, comprising: a substrate and a data line on the substrate; wherein the TFT array substrate further comprises a passivation layer on the substrate, the passivation layer including a first portion of passivation layer over the data line and a second portion of passivation layer over regions other than the data line; and, wherein a thickness of the first portion of passivation layer is less than a thickness of the second portion of passivation layer.

According to still another aspect of the present disclosure, there is provided a display device comprising the abovementioned TFT array substrate

### BRIEF DESCRIPTION OF THE DRAWINGS

These and/or other aspects and advantages of the present disclosure will become apparent and more readily appreciated from the following description of the embodiments, taken in conjunction with the accompanying drawings of which:

FIG. 1 is a sectional view of a TFT array substrate cut along a direction perpendicular to a data line in the TFT array substrate in prior art;

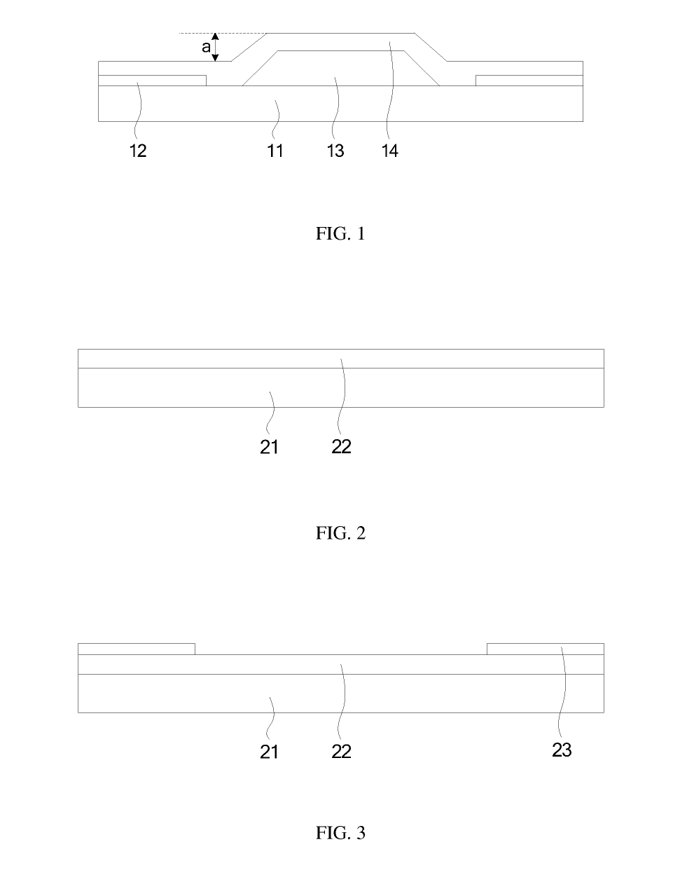

FIGS. 2-7 are procedure views of a method for manufacturing a TFT array substrate according to an embodiment of the present disclosure; and

FIGS. 8-9 are further procedure views of a step S5 of the method for manufacturing the TFT array substrate according to an embodiment of the present disclosure.

### DETAILED DESCRIPTION OF THE EMBODIMENTS

In order to provide a more clear understanding of objects, technique solutions and advantages of the present disclosure, the present disclosure will be further described hereinafter in detail in conjunction with embodiments and with reference to the attached drawings. Obviously, the embodiments illustrated in these drawings are only disclosed simply as an example of an embodiment. For those skilled in the art, other embodiments may be achieved by referring to the following embodiments without involving any inventive steps.

Embodiments of the present disclosure provide a method for manufacturing a TFT array substrate, and the method comprises:

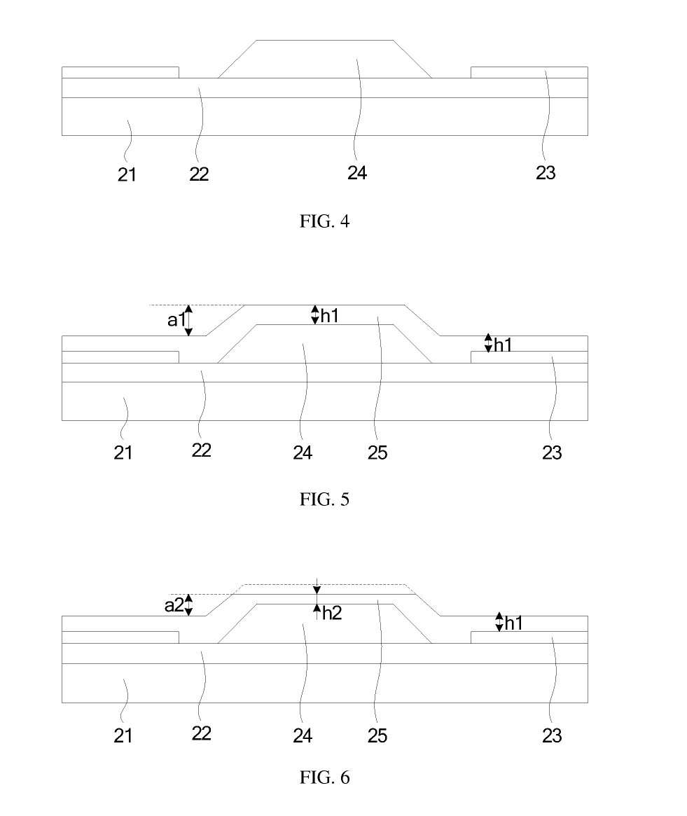

a step S1 of forming a gate insulation layer 22 on a substrate 21 that is formed with a gate line and an active layer thereon, as shown in FIG. 2.

In this step, materials for the gate insulation layer 22 may be insulation materials including silicon nitride, silicon oxide, and the likes; and, a deposition process is adopted as the forming process.

In a subsequent step, the data line will be formed on the gate insulation layer 22, according, it is of assistance to reduce a drop height caused by the greater height of the data line, by reducing a thickness of a portion of the gate insulation layer covered by the data line. Specifically, a portion of the gate insulation layer 22 corresponding to a region where the data line is to be formed is called as a first portion of gate insulation layer, while a portion of the gate insulation layer 22 corresponding to regions other than the region where the data line is to be formed is called as a second portion of gate insulation layer. After forming of the gate insulation layer 22, preferably, the first portion of gate insulation layer is reduced by a second preset thickness so that a thickness of the first portion of gate insulation layer is less than a thickness of the second portion of gate insulation layer.

Process of reducing the first portion of gate insulation layer may be performed by, forming a photoresist, exposing the first portion of gate insulation layer, on the gate insulation layer 22 through a patterning process; and then, reducing the first portion of gate insulation layer by a second preset thickness, by means of etching the first portion of gate insulation layer with the photoresist serving as a mask.

In this step, a thickness by which the first portion of gate insulation layer is reduced (i.e., the second preset thickness) is determined in accordance with thickness of the data line, preferably, it can be 0.4-1.4 times of a thickness of the data line.

Compared with the prior art structure in which the data line is directly formed over the gate insulation layer with uniform thickness such that the data line and other components on the gate insulation layer are laid on a same level, in the present embodiment, the portion of the gate insulation layer 22 corresponding to a region where the data line is to be formed is reduced by certain thickness such that a bottom of the data line (which faces the substrate 21) to be formed later is recessed with relative to bottoms of other components on the gate insulation layer (in order words, the data line is embedded into the gate insulation layer 22), so that a top of the data line (which is away from the substrate 21) has a reduced level in height, reducing a difference in height (i.e., drop height) between the data line and other components on the gate insulation layer 22, thereby improving flatness of an alignment layer to be formed later and alleviating or overcoming problems such as light leakage, contrast decay caused by presence of the drop height.

It should be noted that, the gate line and the active layer are formed respectively in different processing steps and the orders of forming the two may be varied depending on actual requirements, that is, the gate line forming process precedes the active layer forming process, alternatively, the active layer forming process precedes the gate line forming process. Materials for the gate line may be metal material having good electrical conductivity. Materials for the active layer may be selected depending on the type of the TFT array substrate to be manufactured. For example, if the TFT array substrate to be manufactured is an oxide TFT array substrate, materials for the active layer may be oxide semiconductor material.

FIGS. 2-7 are sectional views of a TFT array substrate cut along a direction perpendicular to a data line, in which gate line, active layer, source and drain are not shown.

The method further comprises a step S2 of forming a first electrode 23 on the substrate 21 that is formed with the gate insulation layer 22 thereon, as shown in FIG. 3.

Process of forming the first electrode 23 preferably is performed by disposing a material for the first electrode 23 on the gate insulation layer 22, by means of spin coating, deposition, or evaporation. Materials for the first electrode 23 can be transparent conductive material, e.g., Indium Tin Oxide (ITO). Pattern including the first electrode 23 is formed by etching the material for the first electrode 23 by patterning process.

For liquid crystal display device of different types, the first electrode 23 may have different functions and shapes. For example, if the liquid crystal display device is an Advanced Super Dimension Switch (ADS) liquid crystal display device, the first electrode 23, serving as pixel electrode, is a slit electrode in shape.

The method further comprises a step S3 of forming a data line 24 on the substrate 21 that is formed with the first electrode 23 thereon, as shown in FIG. 4.

Materials for the data line 24 can be metal material having good electrical conductivity. A patterning process is adopted as the forming process. Both the data line 24 and the first electrode 23 are formed on the gate insulation layer 22. Also, a source and a drain of the TFT are formed while the data line 24 is formed. The data line is electrically connected with the source of the TFT, and the first electrode 23 is electrically connected with the drain of the TFT.

Although both the data line 24 and the first electrode 23 are formed on the gate insulation layer 22, a top of the data line 24 is greater in height than that of the first electrode 23 because a thickness of the data line 24 is greater than that of the first electrode 23.

The method further comprises a step S4 of forming a passivation layer 25 on the substrate 21 formed with the data line 24, the passivation layer 25 including a first portion of passivation layer over the data line 24 and a second portion of passivation layer over regions other than the data line 24, as shown in FIG. 5.

In this step, materials for the passivation layer 25 may be insulation materials including silicon nitride, silicon oxide, and the likes; and, a deposition process may be adopted as the forming process.

With the process of depositing the passivation layer 25, the resulted passivation layer 25 has a generally uniform thickness, that is, the first portion of passivation layer 25 over the data line 24 and the second portion of passivation layer 25 over regions other than the data line 24 have almost the same thickness, of h1. Since top of the data line 24 is greater in height than the first electrode 23, a region of the passivation layer over the data line 24 is greater in height than other regions (including the first electrode 23) of the passivation layer, here, a drop height caused by the data line 24 (that is, difference in height between the first portion of passivation layer and the second portion of passivation layer) is a1.

The method further comprises a step S5 of reducing the first portion of passivation layer by a first preset thickness, so that a thickness h2 of the first portion of passivation layer is less than a thickness h1 of the second portion of passivation layer, as shown in FIG. 6.

In this step, the thickness of the first portion of passivation layer is decreased to h2 after reducing the first portion of passivation layer by a first preset thickness (i.e., h1-h2), while the thickness of the second portion of passivation layer remains at h1, accordingly, a difference in height between the first portion of passivation layer and the second portion of passivation layer (i.e., drop height) is decreased to a2, reducing a subsequent difference in height between a portion of the alignment layer corresponding to the data line 24 and a portion of the alignment layer corresponding to regions other than the data line 24, on the passivation layer 25. As a result, liquid crystal molecules near the data line 24 are driven normally, alleviating or overcoming problems of display quality such as light leakage, contrast decay caused by presence of the drop height.

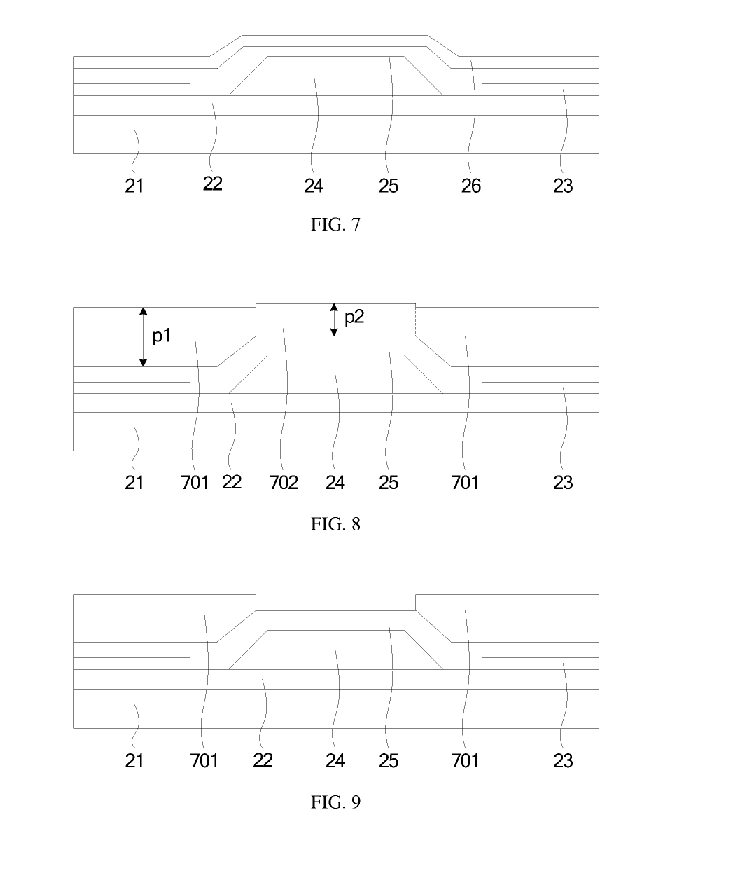

Between the step of depositing the passivation layer 25 and a step of forming a second electrode on the passivation layer 25, that is, before or after this step S5, the method further comprises a step of forming via holes, for connection to external lines, in the passivation layer 25. If the step of forming via holes is ordered between the step of depositing the passivation layer 25 and this step S5, the via holes are formed in the passivation layer 25. The step of reducing the first portion of passivation layer by the first preset thickness may comprise: a substep S51 of forming a photoresist layer having a via hole pattern, on the passivation layer 25, by using a halftone mask, so that a thickness p2 of the photoresist layer 702 over the first portion of passivation layer is less than a thickness p1 of the photoresist layer 701 over the second portion of passivation layer, as shown in FIG. 8.

The halftone mask includes a full exposure area, a partial exposure area and a shading area. After performing the spin coating process of the photoresist (taking a positive photoresist as an example) on the passivation layer 25, the halftone mask is placed to match with the passivation layer 25 such that the full exposure area is aligned with a region where via holes are to be formed, the partial exposure area is aligned with a region where the data line 24 is to be formed and a shading area is aligned with other regions. Then, exposure and development processes are performed. As a result, the required photoresist layer is obtained.

The step of reducing the first portion of passivation layer by the first preset thickness further comprises: a substep S52 of forming the via holes, by etching the passivation layer 25 with the photoresist layer serving as a mask.

The step of reducing the first portion of passivation layer by the first preset thickness further comprises: a substep S53 of exposing a surface of the first portion of passivation layer, by removing the photoresist layer 702 from the first portion of passivation layer with an ashing process, as shown in FIG. 9.

Since the thickness p2 of the photoresist layer 702 over the first portion of passivation layer is less than the thickness p1 of the photoresist layer 701 over the second portion of passivation layer, after complete ashing of the photoresist layer 702 over the first portion of passivation layer, some of the photoresist layer 701 of certain thickness still remains on the second portion of passivation layer.

The step of reducing the first portion of passivation layer by the first preset thickness further comprises: a substep S54 of reducing the first portion of passivation layer by the first preset thickness, with the photoresist layer 701 over the second portion of passivation layer serving as a mask.

With the above substeps S51-S54, the step of forming the via holes in the passivation layer and the step of reducing the first portion of passivation layer by the first preset thickness can be performed in only one patterning process, which is simple and saves an additional patterning process.

Of course, the step of forming the via holes in the passivation layer 25 and the step of reducing the first portion of passivation layer by the first preset thickness can also be performed in two patterning processes, respectively. In such case, specifically, the via holes are formed by forming a photoresist layer having a via hole pattern, on the passivation layer 25; and then, etching the passivation layer 25 with the photoresist layer serving as a mask. While, the first portion of passivation layer is reduced, by the first preset thickness, by forming a photoresist layer having a pattern for the first portion of passivation layer, on the passivation layer 25; and then, reducing the first portion of passivation layer, with the photoresist layer having the pattern for the first portion of passivation layer serving as a mask. In this case, the step of forming the via holes in the passivation layer and the step of reducing the first portion of passivation layer by the first preset thickness can be performed with no particular orders.

In this step, the thickness by which the first portion of passivation layer over the data line 24 is reduced (i.e., the first preset thickness) is determined in accordance with actual thickness of the data line 24, preferably, for example, it can be 0.4-1.4 times, more preferably, 0.5 times, of the thickness of the data line 24, such that the reduced thickness of the first portion of passivation layer is from one third to two third of the original thickness of the first portion of passivation layer. Accordingly, excessive parasitic capacitance between the data line and the subsequent second electrode, which is because of small in thickness of the first portion of passivation layer and adverse influence on quality of the TFT array substrate, will be eliminated. Meanwhile, potential damages on sections of the data line disposed around a peripheral driver chip are alleviated or eliminated

The method further comprises a step S6 of forming a second electrode 26 on the passivation layer 25, as shown in FIG. 7.

Process of forming the second electrode 26 preferably is performed by disposing a material for the second electrode 26 on the gate insulation layer 22, by means of spin coating, deposition, evaporation or the like. Materials for the second electrode 26 can be transparent conductive material, e.g., Indium Tin Oxide (ITO). Pattern including the second electrode 26 is formed by etching the material for the second electrode 26 by a patterning process.

For liquid crystal display device of different types, the second electrode 26 may have different functions and shapes. For example, if the liquid crystal display device is an Advanced Super Dimension Switch (ADS) liquid crystal display device, the second electrode 26, serving as common electrode, is a surface electrode in shape.

Embodiments of the present disclosure also provide a TFT array substrate. Referring to FIG. 7, the TFT array substrate comprises: a substrate 21; a data line 24 on the substrate 21; and a passivation layer 25 on the substrate 21; the passivation layer 25 includes a first portion of passivation layer over the data line 24 and a second portion of passivation layer over regions other than the data line 24, and, a thickness of the first portion of passivation layer is less than a thickness of the second portion of passivation layer.

In the TFT array substrate according to these embodiments, since the thickness of the passivation layer over the data line 24 is less than the thickness of the passivation layer over regions other than the data line 24, it achieves a smaller drop height caused by the data line 24, thereby alleviating or overcoming problems such as light leakage, contrast decay caused by presence of the big drop height in the array substrate, and achieving better quality.

In this embodiment, a difference between the thickness of the second portion of passivation layer and that of the first portion of passivation layer is 0.4-1.4 times of a thickness of the data line 24, such that the drop height is reduced while ensuring stable electrical properties.

The TFT array substrate further comprises: a gate insulation layer 22 formed on the substrate 21 before forming the data line 24, the gate insulation layer including a first portion of gate insulation layer corresponding to a region where the data line is to be formed and a second portion of gate insulation layer corresponding to regions other than the region where the data line is to be formed; and, a thickness of the first portion of gate insulation layer may be less than a thickness of the second portion of gate insulation layer, thereby further reducing the drop height caused by the data line 24 while improving display quality.

The second preset thickness may be 0.4-1.4 times of a thickness of the data line, such that the drop height is reduced while ensuring stable electrical properties.

Correspondingly, embodiments of the present disclosure also provide a display device comprising the above TFT array substrate. Since a drop height of the TFT array substrate according to the embodiments of the present disclosure is smaller than that of the TFT array substrate in prior art, problems such as light leakage, contrast decay caused by presence of the drop height in the array substrate are alleviated or overcome, and the display device according to the embodiments of the present disclosure has a better display quality than the prior art display device.

It should be noted that, the display device according to the embodiments may be liquid crystal panel, electronic paper, and Organic Light-Emitting Diode (OLED) panel, which are used in any products or components having a displaying function, such as, mobile phone, tablet PC, TV, display, notebook PC, digit photo frame, navigating instrument, etc.

It should be understood that the above description is merely used to illustrate specific embodiments of the present disclosure, but not to limit the present disclosure. All of changes, equivalent alternatives, improvements, made within principles and spirit of the disclosure, should be included within the scope of the present disclosure, and the scope of which is defined in the claims and their equivalents.

1. A method of manufacturing a thin film transistor (TFT array substrate, the method comprising:
forming a passivation layer on a substrate formed with a data line, the passivation layer including a first portion of the passivation layer over the data line and a second portion of the passivation layer over regions other than the data line; and
reducing the first portion of the passivation layer by a first preset thickness, so that a thickness of the first portion of the passivation layer is less than a thickness of the second portion of the passivation layer.

2. The method of claim 1, further comprising, between the step of forming the passivation layer on the substrate formed with the data line and the step of reducing the first portion of the passivation layer by the first preset thickness, forming via holes in the passivation layer.

3. The method of claim 2, wherein the step of forming the via holes in the passivation layer and the step of reducing the first portion of the passivation layer by the first preset thickness comprise substeps of:
forming a photoresist layer having a via hole pattern, on the passivation layer, by using a halftone mask, so that a thickness of the photoresist layer over the first portion of the passivation layer is less than a thickness of the photoresist layer over the second portion of the passivation layer;
forming the via holes, by etching the passivation layer with the photoresist layer serving as a mask;
exposing a surface of the first portion of the passivation layer, by removing the
photoresist layer from the first portion of the passivation layer with an ashing process; and
reducing the first portion of the passivation layer by the first preset thickness, with the photoresist layer over the second portion of the passivation layer serving as a mask.

4. The method of claim 2, wherein the step of forming the via holes in the passivation layer and the step of reducing the first portion of the passivation layer by the first preset thickness comprise substeps of:
forming a photoresist layer having a via hole pattern, on the passivation layer;
forming the via holes, by etching the passivation layer with the photoresist layer serving as a mask;
forming a photoresist layer having a pattern for the first portion of the passivation layer, on the passivation layer; and
reducing the first portion of the passivation layer by the first preset thickness, with the photoresist layer having the pattern for the first portion of the passivation layer serving as a mask.

5. The method of claim 1, wherein the first preset thickness is 0.4-1.4 times of a thickness of the data line.

6. The method of claim 1, further comprising, before the step of forming the data line,
forming a gate insulation layer, the gate insulation layer including a first portion of the gate insulation layer corresponding to a region where the data line is to be formed and a second portion of the gate insulation layer corresponding to regions other than the region where the data line is to be formed; and
reducing the first portion of the gate insulation layer by a second preset thickness, so that a thickness of the first portion of the gate insulation layer is less than a thickness of the second portion of the gate insulation layer.

7. The method of claim 6, wherein the second preset thickness is 0.4-1.4 times of a thickness of the data line.

8. A thin film transistor (TFT array substrate, comprising:
a substrate; and
a data line on the substrate;
wherein the TFT array substrate further comprises a passivation layer on the substrate, the passivation layer including a first portion of the passivation layer over the data line and a second portion of the passivation layer over regions other than the data line; and, wherein a thickness of the first portion of the passivation layer is less than a thickness of the second portion of the passivation layer.

9. The TFT array substrate of claim 8, wherein a difference between the thickness of the second portion of the passivation layer and that of the first portion of the passivation layer is 0.4-1.4 times of a thickness of the data line.

10. The TFT array substrate of claim 8, further comprising:
a gate insulation layer formed on the substrate before forming the data line, the gate insulation layer including a first portion of the gate insulation layer corresponding to a region where the data line is to be formed and a second portion of the gate insulation layer corresponding to regions other than the region where the data line is to be formed; and
wherein a thickness of the first portion of the gate insulation layer is less than a thickness of the second portion of the gate insulation layer.

11. The TFT array substrate of claim 10, further comprising:
a gate line formed under the data line and on the substrate, wherein the second preset thickness is 0.4-1.4 times of a thickness of the data line.

12. A display device comprising a TFT array substrate of claim 8.

13. The display device of claim 12, wherein, in the TFT array substrate, a difference between the thickness of the second portion of the passivation layer and that of the first portion of the passivation layer is 0.4-1.4 times of a thickness of the data line.

14. The display device of claim 12, wherein the TFT array substrate further comprises:
a gate insulation layer formed on the substrate before forming the data line, the gate insulation layer including a first portion of the gate insulation layer corresponding to a region where the data line is to be formed and a second portion of the gate insulation layer corresponding to regions other than the region where the data line is to be formed; and, wherein a thickness of the first portion of the gate insulation layer is less than a thickness of the second portion of the gate insulation layer.

15. The display device of claim 14, wherein the TFT array substrate further comprises: a gate line formed under the data line and on the substrate, wherein the second preset thickness is 0.4-1.4 times of a thickness of the data line.
